(19) United States
(12) Patent Application Publication
(10) Pub. No.: US 2012/0309180 A1
(43) Pub. Date: Dec. 6, 2012

(54) METHOD OF FORMING A RETROGRADE MATERIAL PROFILE USING ION IMPLANTATION

(75) Inventors: Ludovic Godet, Boston, MA (US); George D. Papasouliotis, North Andover, MA (US)

(73) Assignee: VARIAN SEMICONDUCTOR EQUIPMENT ASSOCIATES, INC., Gloucester, MA (US)

(21) Appl. No.: 13/588,793

(22) Filed: Aug. 17, 2012

Related U.S. Application Data
(62) Division of application No. 12/044,619, filed on Mar. 7, 2008.

(51) Int. Cl. H01L 21/265

(52) U.S. Cl. 438/527; 257/E21.334

(57) ABSTRACT

A method of forming a retrograde material profile in a substrate includes forming a surface peak profile on the substrate. Ions are then implanted into the substrate to form a retrograde profile from the surface peak profile, at least one of an ion implantation dose and an ion implantation energy of the implanted ions being chosen so that the retrograde profile has a peak concentration that is positioned at a desired distance from the surface of the substrate.

This is a divisional application of the nonprovisional patent application entitled “A Method of Forming a Retrograde Material Profile Using Ion Implantation,” filed Mar. 7, 2008 and assigned U.S. application Ser. No. 12/044,619, the disclosure of which is hereby incorporated by reference.

The section headings used herein are for organizational purposes only and should not to be construed as limiting the subject matter described in the present application.

### BACKGROUND OF THE INVENTION

Thin film deposition has been widely used in the semiconductor and other industries for many decades. There are numerous methods for depositing thin films on substrates, which are well known in the art. For example, thin films can be deposited on substrates using various types of chemical vapor deposition, atomic layer deposition, and molecular beam epitaxy. Such deposited thin films typically have a surface level profile. The term “surface level profile” is defined herein as a film profile where the peak concentration of the film material is on the surface of the substrate rather than at some distance into the surface of the substrate.

Ion implantation has been used in the semiconductor and other industries for many decades to modify the composition of substrate material. In particular, beam-line and cluster beam ion implantation systems are widely used today in the semiconductor industry. Beam-line and cluster beam ion implantation systems accelerate ions with an electric field and then filter the ions according to their mass-to-charge ratio to select the desired ions for implantation. These systems have excellent process control, excellent run-to-run uniformity, and provide highly uniform doping across the entire surface of state-of-the art semiconductor substrates.

More recently, plasma doping has been used to dope substrates. Plasma doping is sometimes referred to as PLAD or plasma immersion ion implantation (PIII). Plasma doping systems have been developed to meet the doping requirements of state-of-the-art electronic and optical devices. Plasma doping systems are fundamentally different from conventional beam-line and cluster beam ion implantation systems. Plasma doping systems immerse the target in a plasma containing dopant ions and then bias the target with a series of negative voltage pulses. The term “target” is defined herein as the substrate being ion implanted. The negative bias on the target repels electrons from the target surface thereby creating a sheath of positive ions. The electric field within the plasma sheath accelerates ions toward the target thereby implanting the ions into the target surface.

### BRIEF DESCRIPTION OF THE DRAWINGS

The invention, in accordance with preferred and exemplary embodiments, together with further advantages thereof, is more particularly described in the following detailed description, taken in conjunction with the accompanying drawings. The drawings are not necessarily to scale, emphasis instead generally being placed upon illustrating principles of the invention.

FIG. 1A illustrates a process diagram of a method of forming a retrograde ion implantation profile from a surface peaked dopant profile in a substrate according to the present invention.

FIG. 1B illustrates a process diagram of a method of forming a retrograde material profile from a deposited thin film profile according to the present invention.

FIG. 2 illustrates plots of Boron ion implantation profiles before and after two different profile modifying implants according to the present invention.

FIG. 3 illustrates bar graphs of experimental data for resistivity in ohms/sq for substrates implanted with dopant ions before and after performing profile modifying implants according to the present invention for three different annealing protocols.

### DETAILED DESCRIPTION

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

It should be understood that the individual steps of the methods of the present invention may be performed in any order and/or simultaneously as long as the invention remains operable. Furthermore, it should be understood that the apparatus and methods of the present invention can include any number or all of the described embodiments as long as the invention remains operable.

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teachings herein will recognize additional implementations, modifications, and embodiments, as well as other fields of use, which are within the scope of the present disclosure as described herein. For example, although some embodiments of the present invention are described in connection with forming a surface level ion implantation profile and then forming a retrograde material profile, the methods of forming a retrograde material profile can be used with any type of surface layer material profile. Furthermore, the surface peak profile can be formed by any means.

Three dimensional device structures are now being developed to increase the available surface area of ULSI circuits as well as to extend the device scaling to sub 65 nm dimensions. For example, three-dimensional trench capacitors used in DRAMs, and numerous types of devices using vertical channel transistors, such as FinFETs (Double or Triple gate) and recessed channel array transistors (RCAT), are being developed for state-of-the art systems. Many of these three-dimensional devices require very precise control of the depth of thin film and ion implant profiles in the substrate. In addition, numerous other types of modern electronic and optical devices and nanotechnology microstructures require very precise control of the depth of thin film and ion implant dopant profiles in the substrate.

Ion implant dopant profiles formed by plasma doping typically peak at or close to the surface of the substrate. Ion implant dopant profiles formed by plasma doping are essentially combinations of many individual ion profiles at different energy levels. The ion implant dopant profile depends on the relative abundance of each ion species as well as the individual energy distributions of the ions prior to entering the surface of the substrate. The ion implant dopant profile also depends upon the control of the deposition and etching which results from the plasma doping process. The relatively low energies of the individual ion profiles and the deposition and etching which results from the ion implantation process causes the plasma doping profiles to have peak values at or near the surface of the substrate, which is undesirable for many applications.

It is difficult to precisely control the depth of ion implanted layers using plasma doping for many reasons. For example, during plasma doping, there could be some unintentional etching of the surface of the substrate caused by physically sputtering and chemical etching. In addition, there could be some unintentional deposition on the surface of the substrate. Furthermore, there can be a significant ion implant energy distribution due to many factors, such as the presence of multiple ion species, collisions between ions, non uniformities in the plasma sheath, presence of secondary electron emissions, displacements currents formed due to parasitic impedances, and the application of non-ideal bias pulses.

Surface-peak dopant profiles are very sensitive to post deposition or post implant processes because most of the maximum peak concentration of deposited or implanted material is located at or near the surface of the substrate. In particular, the photo-resist strip process typically performed after implantation will remove a significant amount of dopant material near the surface.

Many devices require that retrograde profiles be formed from surface peak ion implant dopant profiles and from deposited thin films. The term “retrograde profile” is defined herein as a profile where the peak concentration of the profile is below the surface of the substrate.

One aspect of the present invention relates to a method of modifying a dopant profile. In particular, one aspect of the present invention relates to a method of modifying a surface peaked ion implant dopant profile to form a retrograde dopant profile. Another aspect of the present invention relates to a method of modifying a deposited thin film with a surface peak profile to form a retrograde thin film in the substrate.

The methods of the present invention include performing a profile modifying ion implantation step after a surface layer ion implant or after a thin film deposition step has been performed. The profile modifying ion implant step is a dedicated ion implant step that changes a surface peak profile to a retrograde material profile, while maintaining the properties of the material.

Known methods for using ion beams to modify surface layer dopant profiles do not form retrograde profiles as described herein. For example, one known method, which is disclosed in U.S. Reissue Pat. No. RE39,988, describes a two-step doping process that includes depositing dopant material onto a semiconductor surface and then performing pulsed laser or ion beam processing. However, the two-step process described in RE39,988 only increases the surface concentration of dopant atoms/molecules. The two-step process does not form a retrograde profile at a desired depth as describe herein. Instead, the laser or ion beam processing step melts a portion of the semiconductor to a desired depth.

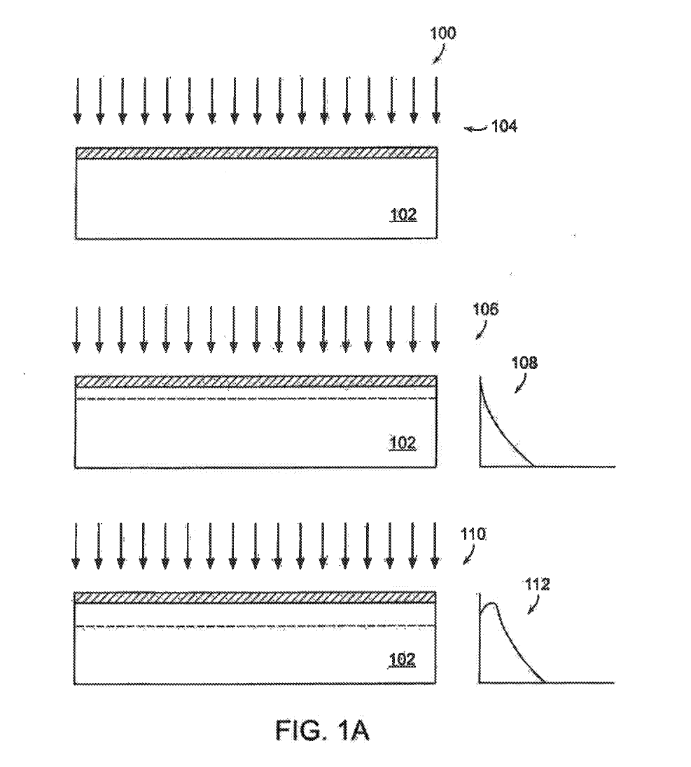

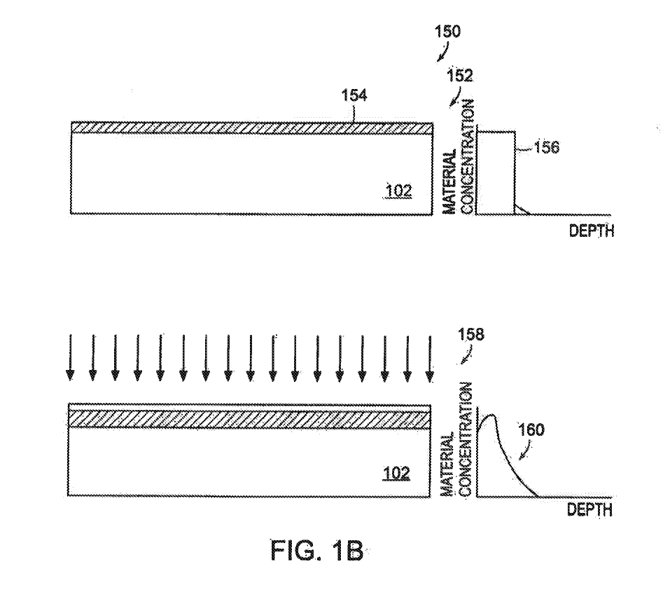

FIG. 1A illustrates a process diagram 100 of a method of forming a retrograde ion implantation profile from a surface peaked dopant profile in a substrate according to the present invention. In a first step 104, an optional pre-amorphization ion implant is performed prior to plasma doping. Pre-amorphization is commonly used to avoid dopant channeling into silicon substrates. Dopant channeling is undesirable because the channeling increases the junction depth. Therefore, in devices having ultra-shallow junctions it is highly desirable to avoid channeling of the dopant ion beam by the silicon lattice.

For example, in one embodiment, pre-amorphization is performed by ion implanting at least one of GeH₄, GeF₄, SiH₄, SiF₄, He, Ne, Ar, Kr, and Xe. Any type of ion implanting can be used to ion implant the pre-amorphization ions, such as plasma doping, beam line ion implantation, and cluster beam ion implanting. The pre-amorphization reduces dopant ion channeling and, therefore, results in more abrupt and shallow profiles, which are desirable for many devices and necessary for many other devices, such as devices with ultra-short junction depths.

In a second step 106, an ion implant is performed to achieve the desired surface level dopant profile 108. The ion implant can be any type of ion implant, such as an N-type or P-type ion implant. For example, the ion implant can be performed with B₂H₆, BI₃, BF₃, AsH₃, AsF₅, PH₃, PF₃, and N₂ feed gases. Any type of ion implanting can be used to ion implant the desired surface level dopant profile 108, such as plasma doping, beam line ion implantation and cluster beam ion implanting. In one embodiment, the ion implant is performed with plasma doping. Plasma doping is performed by positioning the substrate 102 in a plasma doping apparatus. The plasma doping apparatus immerses the substrate in a plasma containing the dopant ions. The substrate 102 is then biased with a series of negative voltage pulses that repel electrons from the surface of the substrate 102, thereby creating a sheath of positive ions. The electric field within the plasma sheath accelerates ions toward the substrate 102, thereby implanting the ions into the surface of the substrate 102.

In addition, the methods of modifying dopant profiles after N-type or P-type ion implants to form retrograde ion implantation profiles can also be used with co-implantation of ions such as C, F, and Ge ions. Co-implantation can improve the activation of the dopant species. Co-implantation also tends to increase the junction depth. However, when co-implantation is combined with pre-amorphization, the increase in the junction depth is minimized.

In a third step 110, a dedicated profile modifying ion implant is performed. In many embodiments, the dedicated profile modifying ion implant step comprises implanting inert chemistry ions, such as noble gas ions, into the surface of the substrate 102. Thus, in one embodiment, the dedicated retrograde ion implant comprises implanting noble gas ions, such as He, Ne, Ar, Kr, or Xe. Noble gas ions work well because they do not change the chemistry of the implanted ions or of the deposited thin film. However, one skilled in the art will understand that the methods of the present invention can use numerous other types of ions to form retrograde profiles. For example, in other embodiments, methods of the present invention use Ge, Si, or C ions to form retrograde profiles. Furthermore, the profile modifying implant step can be performed by any type of ion implantation means including beamline ion implantation, plasma immersion ion implantation, or any other ion or molecular cluster implantation method.

The process described in the present invention can be carried out on planar substrates, as well as on substrates comprising three-dimensional structures. The substrate surface may be crystalline, amorphous, or polycrystalline silicon, metals, such as Cu and Al, dielectric materials, photoresist, or any combinations thereof.

The shape of the retrograde ion implant profile 112 also depends upon the profile modifying ion implantation parameters. These parameters include the implant energy, implant dose, dose rate, RF signal, bias voltage, and substrate temperature. In addition, the junction depth of the implanted material can be controlled by changing the profile modifying ion implant parameters. In some embodiments, the junction depth of the ion implanted material is maintained during the profile modifying ion implant. In some embodiments, at least one ion implantation parameter is modulated to achieve a desired retrograde profile.

In some embodiments, the implant voltage is changed during the profile modifying ion implant in order to improve the control of the shape of the dopant profile. For example, the implant voltage could be slowly increased during the profile modifying ion implant step to move the dopant profile deeper into the junction. Also, the implant voltage could be reduced during the profile modifying ion implant step to improve the profile abruptness.

There are several other factors that determine which ion is best suited for use in the profile modifying implant step to form the desired retrograde ion implant profile. For example, lighter ions may produce less sputtering and less end of range (EOR) damage in the substrate. Using relatively light ions have been found to form retrograde ion implant profiles with insignificant surface damage for many applications. In addition, lighter ions, such as He and Ne, more efficiently out-diffuse during anneal processes, which can improve device performance. Also, heavier ions produce more sputtering and more end of range (EOR) damage in the substrate.

The optional pre-amorphization ion implant performed in the first step 104, the ion implant performed in the second step 106, and the profile modifying ion implant performed in the third step 110 can be performed sequentially in the same plasma doping chamber or can be performed in separate plasma doping chambers of a plasma doping cluster tool. Alternatively, the optional pre-amorphization implant performed in the first step 104, the ion implant performed in the second step 106, and the profile modifying implant performed in the third step 110 can be performed in separate implantation tools and/or chambers, which can employ any type of implantation technology, such as beamline, plasma immersion, and molecular cluster. In a cluster tool configuration, chambers performing substrate preparation (e.g., surface pre-cleaning) and post-processing steps (e.g. annealing) can be included.

FIG. 1B illustrates a process diagram 150 of a method of forming a retrograde material profile from a deposited thin film profile according to the present invention. In a first step 152, a thin film of material 154 is deposited by any means to form a thin film material profile 156. For example, a thin film of material can be deposited by chemical vapor deposition, atomic layer deposition, or by various other thin film deposition and growth methods, such as PVD, MBE, and MOCVD, that are known in the art. The thin film material profile 156 for deposited thin films is typically a step profile as shown in FIG. 1B.

In a second step 158, a profile modifying implant is performed. In many embodiments, the retrograde ion implant step comprises implanting inert chemistry ions, such as noble gas ions, into the surface of the substrate 102. Thus, in one embodiment, the dedicated retrograde ion implant comprises implanting noble gas ions, such as He, Ne, Ar, Kr, or Xe. However, one skilled in the art will understand that the methods of the present invention can use numerous other types of ions to form retrograde thin film profiles.

The retrograde ion implant changes the shape of the material profile 154 to form a retrograde profile 160. The shape of the resulting retrograde material profile 160 depends on the type of ion. The shape of the resulting retrograde material profile 160 also depends upon the profile modifying ion implantation parameters. These parameters include the implant energy, implant dose, dose rate, RF signal, bias voltage, and substrate temperature. In some embodiments, at least one ion implantation parameter is modulated to achieve a desired retrograde profile.

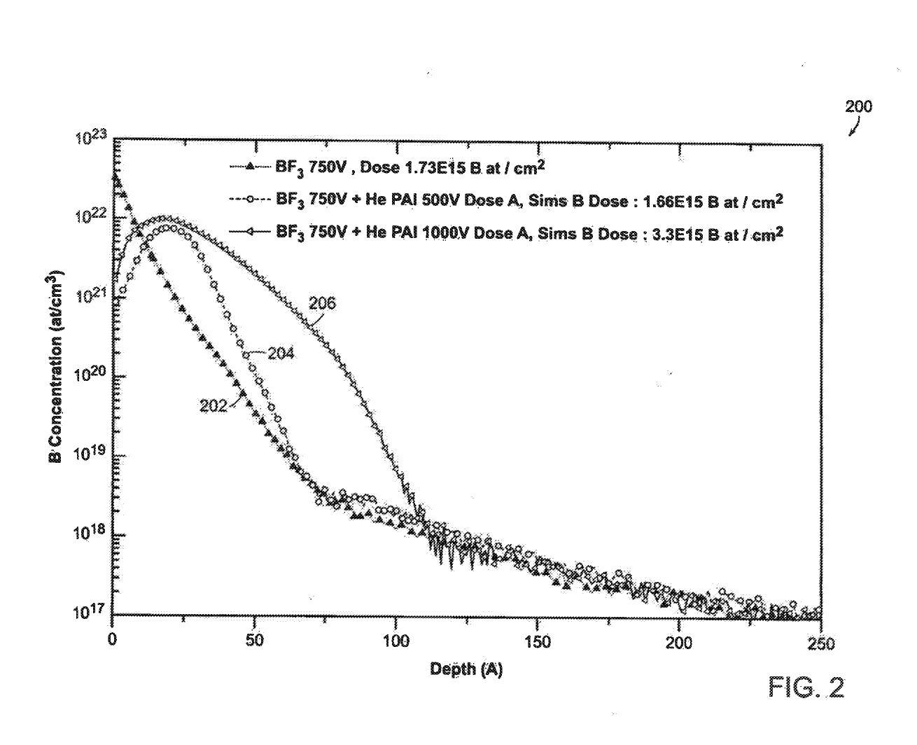

FIG. 2 illustrates plots of Boron ion implantation profiles before and after two different profile modifying implants according to the present invention. Referring to FIGS. 1A and 2, the plots 200 present Boron ion concentration in atoms per cubic meter as a function of depth into the substrate 102 in angstroms. The data shown in the plots 200 were experimentally obtained by stripping the wafers of photoresist or other masking materials and performing SIMS measurements, which have been shown to accurately measure Boron concentration as a function of depth for high dose implants.

The Boron ion implant was performed by plasma doping the substrate 102 with BF₃ gas, and a 750 Volt substrate bias. The original Boron ion implantation dose was 1.73 10¹⁵ Boron atoms/cm². A first plot 202 of the initial Boron ion implantation profile directly after plasma doping is shown as Boron ion concentration as a function of depth into the surface of the substrate. The first plot 202 of the Boron ion concentration directly after the plasma doping peaks at the surface of the substrate 102 at a concentration of about 3 10²² Boron atoms/cm².

A second plot 204 of Boron ion concentration as a function of depth into the surface of the substrate 102 is shown after a profile modifying 500 Volt He ion implant. The 500 Volt profile modifying He implant was performed directly after the original 750 Volt 1.73 10¹⁵ dose Boron ion implant. The Boron ion implantation dose after the first profile modifying He implant is 1.66 10¹⁵ Boron atoms/cm². Boron ion concentration is presented in atoms per cubic centimeter as a function of depth into the substrate 102 in Angstroms.

The plot 204 indicates that the Boron ion concentration now peaks away from the surface of the substrate 102. That is, the Boron ion implant profile has become a retrograde ion implant profile. The data in the second plot 204 indicates that the first retrograde profile is about 25 Angstroms from the surface of the substrate 102 with a relatively rapid change in Boron ion concentration as a function of distance into the substrate 102. Therefore, the profile modifying He ion implant converted the surface peaked dopant profile to a retrograde dopant profile and maintained the Boron retained dose into the silicon. The data in the second plot 204 also indicates that the junction depth is maintained and that the profile is more abrupt after the He ion implant.

A third plot 206 of Boron ion concentration as a function of depth into the surface of the substrate 102 is shown after a 1,000 Volt He profile modifying ion implant. The 1,000 Volt profile modifying implant was performed directly after the original 750 Volt 1.73 10¹⁵ dose Boron ion implant. The Boron ion implantation dose after the second profile modifying He implant was 3.3 10¹⁵ Boron atoms/cm². Boron ion concentration is presented in atoms per cubic centimeter as a function of depth into the substrate 102 in Angstroms.

The third plot 206 illustrates the Boron ion concentration as a function of depth into the surface of the substrate 102 after a He ion implant was performed. The data in the third plot 206 indicates that the second retrograde profile is also about 25 Angstroms from the surface of the substrate 102. However, the third plot 206 indicates a relatively slow change in Boron ion concentration as a function of distance into the substrate 102. The data in the third plot 206 also indicates that the junction depth defined at 5 10¹⁸ atoms/cm³ is shifted from 6.9 nm to 10.2 nm during the 1,000 Volt Helium profile modifying implant. Thus, the second and third plots 204, 206 indicate that the profile shape, the abruptness of the dopant concentration, and the junction depth into the substrate 102 can be controlled by controlling the energy and dose of the profile modifying implant.

The methods of the present invention can be used to modify dopant profiles after an any type of ion implant to form retrograde implant profiles. Such retrograde ion implant profiles are desirable because they are much less sensitive to post ion implant processing, such as photoresist stripping and implant annealing. Similarly, the methods of the present invention can be used to form retrograde material profiles from deposited thin films. Such retrograde material profiles are much less sensitive to post deposition processes.

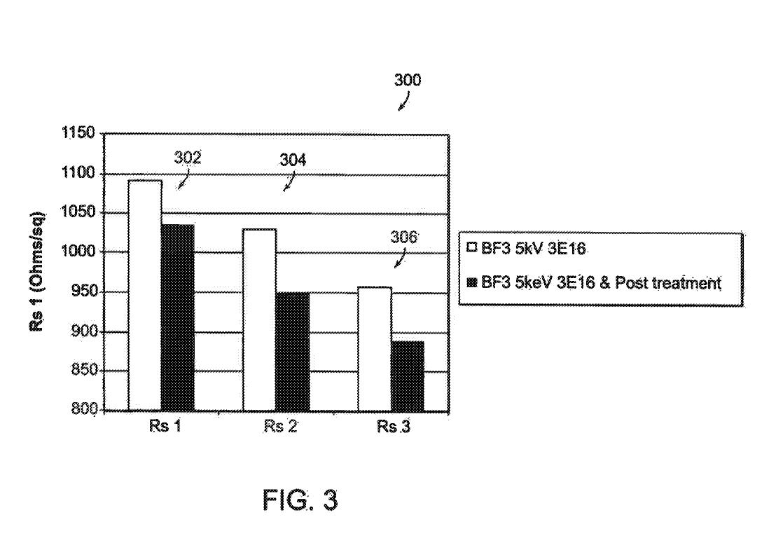

FIG. 3 illustrates plots 300 of experimental data for resistivity in ohms/sq for substrates implanted with dopant ions before and after performing profile modifying implants according to the present invention for three different annealing protocols. Data is presented for an initial 5 KV Boron ion implant using BF₃ feed gas with a dose equal to 3 10¹⁶ Boron atoms/cm². The Boron ions were implanted into a polysilicon substrate. A He profile modifying ion implant was performed as described herein. The photoresist was stripped off the polysilicon substrates after the ion implants. The polysilicon substrates were then annealed using three different annealing protocols before the resistivity measurements were performed.

The data in the plots 300 indicates that the resistivity in ohms/sq is reduced for each of the three annealing protocols 302, 304, and 306 after the profile modifying ion implants are performed. These data suggest that the profile modifying ion implants do indeed improve the activation of Boron ions.

### EQUIVALENTS

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit, and scope of the invention.

What is claimed is:

1. A method of forming a retrograde material profile in a substrate, the method comprising:
forming a surface peak profile on the substrate, wherein the forming the surface peak profile on the substrate comprises ion implanting dopant ions into the substrate to form a dopant ion surface peak profile; and
implanting ions into the substrate to form a retrograde profile from the surface peak profile, at least one of an ion implantation dose and an ion implantation energy of the implanted ions being chosen so that the retrograde profile has a peak concentration that is positioned at a desired distance from the surface of the substrate.

2. The method of claim 1 wherein the implanting the ions into the surface peak profile comprises implanting inert ions.

3. The method of claim 1 further comprising performing amorphization of the surface of the substrate prior to forming the surface peak profile on the substrate.

4. The method of claim 1 wherein at least one of the energy and the dose of the ions implanted into the surface of the substrate is adjusted to substantially maintain a junction depth of the surface peak profile.

5. The method of claim 1 wherein at least one of the energy and the dose of the ions implanted into the substrate is chosen to achieve a desired abruptness of the surface peak profile as a function of distance into the substrate.

6. The method of claim 1 further comprising controlling a temperature of the substrate so that a peak concentration of the retrograde profile is located a desired distance from the surface of the substrate.

7. The method of claim 1 further comprising modulating at least one ion implantation parameter to achieve a desired retrograde profile.

8. The method of claim 1 further comprising controlling at least one of process gas flow, chamber pressure, RF source power, and ion energy during the implanting ions into the substrate to achieve at least one of a predetermined dopant profile and a junction depth.

9. The method of claim 1 further comprising controlling at least one of process gas flow, chamber pressure, RF source power, and ion energy during the implanting ions into the substrate to achieve a predetermined concentration of dopant at the substrate surface.

10. A method of forming a retrograde ion implantation profile in a substrate, the method comprising:
implanting a first species of ions into the substrate thereby forming a first ion implantation profile; and
implanting a second species of ions into the surface of the substrate, at least one of an ion implantation dose and an ion implantation energy of the second species of ions being chosen to modify the first ion implantation profile to have a peak concentration that is positioned a desired distance from the surface of the substrate.

11. The method of claim 10 wherein the implanting the first and the second species of ions comprises at least one of plasma doping, beam line ion implanting, and molecular cluster implanting.

12. The method of claim 10 wherein the implanting the second species of ions comprises implanting inert ions.

13. The method of claim 12 wherein the inert ions comprise noble gas ions.

14. The method of claim 10 further comprising performing amorphization of the surface of the substrate prior to implanting the first species of ions into the substrate.

15. The method of claim 10 wherein at least one of the energy and the dose of the second species of ion is adjusted to maintain a junction depth of the first ion implantation profile.

16. The method of claim 10 wherein at least one of the energy and the dose of the second species of ion is adjusted to achieve a desired abruptness of the retrograde ion implant profile as a function of distance into the substrate.

17. The method of claim 10 further comprising controlling a temperature of the substrate so that a peak concentration of the retrograde material profile is located a desired distance from the surface of the substrate.

18. The method of claim 10 further comprising co-implanting at least one of C, F, and Ge ions into the surface of the substrate.
